(19) United States
(12) Patent Application Publication
(10) Pub. No.: US 2009/0236506 A1
(43) Pub. Date: Sep. 24, 2009

(54) LIGHT-EMITTING DEVICE ON-WAFER TEST SYSTEMS AND METHODS

(75) Inventors: Robert G. Dudgeon, Londonderry, NH (US); Michael G. Brown, Tyngsboro, MA (US); Robert F. Karlicek, JR., Chelmsford, MA (US)

Correspondence Address: LUMINUS DEVICES , INC.;C/O WOLF, GREENFIELD & SACKS , P.C., 600 ATLANTIC AVENUE, BOSTON, MA, 02210-2206, US

(73) Assignee: Luminus Devices, Inc., Billerica, MA (US)

(21) Appl. No.: 12/275,040

(22) Filed: Nov. 20, 2008

Related U.S. Application Data
(60) Provisional application No. 60/989,336, filed on Nov. 20, 2007.

(51) Int. Cl. G01J 1/00; H01L 33/00

(52) U.S. Cl. 250/228; 257/48; 257/E33.076

(57) ABSTRACT

On-wafer test systems and methods for light-emitting devices, such as light-emitting diodes (LEDs), are provided. The test system may be designed, for example, to characterize the light output from the LED die (e.g., power in Lumens).

### RELATED APPLICATIONS

This application claims priority to U.S. Provisional Patent Application Ser. No. 60/989,336, filed Nov. 20, 2007, which is incorporated herein by reference.

### FIELD

The present embodiments are drawn generally towards on-wafer test systems and methods for light-emitting devices, and more specifically to on-wafer test systems and methods for light-emitting diodes (LEDs).

### BACKGROUND

A light-emitting diode (LED) can provide light in a more efficient manner than an incandescent and/or a fluorescent light source. The relatively high power efficiency associated with LEDs has created an interest in using LEDs to displace conventional light sources in a variety of lighting applications. For example, in some instances LEDs are being used as traffic lights and to illuminate cell phone keypads and displays.

Typically, an LED is formed of multiple layers, with at least some of the layers being formed of different materials. In general, the materials and thicknesses selected for the layers influence the wavelength(s) of light emitted by the LED. In addition, the chemical composition of the layers can be selected to promote isolation of injected electrical charge carriers into regions (e.g., quantum wells) for relatively efficient conversion to light. Generally, the layers on one side of the junction where a quantum well is grown are doped with donor atoms that result in high electron concentration (such layers are commonly referred to as n-type layers), and the layers on the opposite side are doped with acceptor atoms that result in a relatively high hole concentration (such layers are commonly referred to as p-type layers).

LEDs also generally include contact structures (also referred to as electrical contact structures or electrodes), which are conductive features of the device that may be electrically connected to a power source. The power source can provide electrical current to the device via the contact structures, e.g., the contact structures can deliver current along the lengths of structures to the surface of the device within which light may be generated.

### SUMMARY

On-wafer test systems and methods for light-emitting devices, such as light-emitting diodes (LEDs), are provided.

In one embodiment, an on-wafer LED test system is provided. The system comprises a wafer including an LED die designed to emit light and a light-collection component configured to collect substantially all of the emitted light and to scatter the emitted light to produce a distribution of scattered light. The system further comprises a detector associated with the light-collection component and designed to detect a portion of the scattered light.

In another aspect embodiment, a method of performing an on-wafer LED test is provided. The method comprises collecting within a light-collection component substantially all light emitted by a LED die of a wafer. The method further comprises scattering the emitted light within the light-collection component to produce a distribution of scattered light and detecting a portion of the scattered light.

For purposes of clarity, not every component is labeled in every figure. Nor is every component of each embodiment of the invention shown where illustration is not necessary to allow those of ordinary skill in the art to understand the invention. All patent applications and patents incorporated herein by reference are incorporated by reference in their entirety. In case of conflict, the present specification, including definitions, will control.

### BRIEF DESCRIPTION OF FIGURES

FIG. 1 is a cross-section view of an on-wafer light-emitting die test system, in accordance with one embodiment;

FIG. 2 is a perspective view of a probe card of the on-wafer light-emitting die test system of FIG. 1, in accordance with one embodiment;

FIG. 3 is a flowchart of a method for performing on-wafer testing of a light-emitting die, in accordance with one embodiment; and

FIG. 4 is a schematic of a light-emitting die, in accordance with one embodiment.

### DETAILED DESCRIPTION

In some embodiments presented here, an on-wafer light-emitting die (e.g., LED die) test system comprises an integrating sphere configured to collect at least some light emitted by a light-emitting die (e.g., LED die) of a wafer. In some embodiments, an on-wafer light-emitting die (e.g., LED die) test system comprises a light-collection component configured to collect substantially all light emitted by a light-emitting die (e.g., LED die) of a wafer. The test system may be designed, for example, to characterize the light output from the LED die (e.g., power in Lumens).

The inventors have appreciated that on-wafer test of large die area LEDs, especially large die area LEDs (e.g., surface roughened and/or patterned LEDs), may be problematic since conventional LED on-wafer test systems may only detect light from a localized test detection point, such as a photodetector located at a fixed angle (e.g., normal, at 60 degrees off-normal, at 45 degrees off-normal) to the LED surface. Such conventional LED on-wafer test systems may inappropriately measure light emission from large-area LEDs since light emission at a given angle may be sensitive to variations in the light extraction features that may be present on the surface of the LED. Examples of light extraction features may include surface roughening and/or patterning (e.g., patterned holes). Additionally, some large-area LEDs may possess light extraction features that can collimate the emitted light. Any process fabrication variation may lead to variation in the light extraction features which can also alter the collimation of emitted light. Variation in light collimation can greatly influence the light intensity at a given collection angle (e.g., normal, at 60 degrees off-normal, at 45 degrees off-normal) even though the total emitted light may be similar. In such circumstances, conventional on-wafer LED test systems lead to erroneous light output measurements for the LED dies.

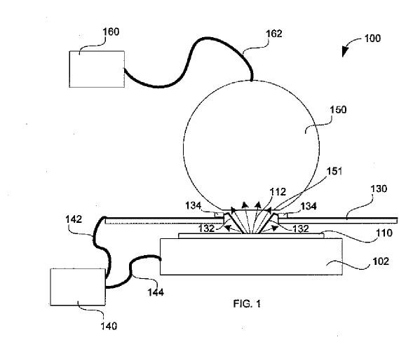

FIG. 1 illustrates a light-emitting die on-wafer test system 100, in accordance with one embodiment. In some embodiments, on-wafer test system 110 may include a light-collection component configured to collect substantially all light emitted by a LED die of a wafer. In some embodiments, a light-collection component may include a light integrating sphere 150. Integrating sphere 150 may include a light-collection opening 151 over which a light-emitting die may be disposed.

The light-collection component has a hollow cavity. An interior surface of the light-collection component may define the cavity. In embodiments in which the light-collection component is an integrating sphere, the cavity is spherical shaped. It should be understood that the cavity of the light-collection component may have other suitable shapes including a cylindrical shape and an elliptical shape.

An inner surface of the light-collection component is generally coated with a material that affects light reflectivity. For example, the interior surface may be coated with a material that exhibits high diffuse reflectivity. The coating may reflect white light. Suitable coating materials include certain polymeric materials (e.g., Teflon-based materials) and certain paints (e.g., barium sulfate), amongst others.

The light-collection component is designed to scatter (i.e., diffuses) light. In some cases, it may be preferred that the light-collection component scatters light uniformly such that there is a uniform distribution of scattered light across the interior surface of the light-collection component. Thus, in these embodiments, light rays emitted from the light-emitting die that are incident on any point on the interior surface of the light-collection component are, by multiple scattering reflections, distributed equally to all other such points on the interior surface. In this manner, effects of the original direction of such light on the resulting measurements are minimized.

The system can have a light detector that detects the light scattered by the light-collection component. Any type of suitable detector may be used including conventional photodetectors. It is typically preferable to position the detector within the light-collection component such that the detector only detects the light scattered by the light-collection component. That is, positioned at a location such that light emitted directly from the LED die does not impinge upon the detector. In some embodiments, one or more baffles may be used to prevent, or limit, directly emitted light from the LED die impinging upon the detector.

On-wafer test system 100 may include a collection fiber (e.g., optical fiber) 162 that can transmit the light collected by the integrating sphere 150. Collection fiber 162 may provide the collected light to a photodetector system 160 that can convert collected light into an electrical signal. In some embodiments, photodetector system 160 may include a spectrometer that can provide light intensity versus wavelength data. In some embodiments, photodetector system may provide an integrated light intensity over a desired wavelength range (e.g., visible range). In some embodiments, photodetector system may provide an integrated photometric light intensity over a desired wavelength range (e.g., visible range), as may be provided my multiply the light intensity with a photometric response curve.

In some preferred embodiments, the light-emitting die that may be tested may include light-emitting diode (LED) dies. However, it should be understood that in other light-emitting dies may also be suitable. A wafer 110 being tested may include a plurality of light-emitting dies, for example light-emitting dies arranged in a 2D array arrangement. In some embodiments, the light-emitting die may include large-area dies having an area greater than about 1 mm² (e.g., greater than about 3 mm², greater than about 5 mm², greater than about 8 mm², greater than about 10 mm²). In some embodiments, the light-emitting die can include light extraction features (e.g., patterning and/or surface roughness), as is described further herein.

In some embodiments, the light-emitting dies may include top contact bond pads that allow for electrical contact via the top-side of the dies. In some embodiments, the backside of the wafer 110 may be electrically conductive and may serve as a backside electrical contact to the dies. For example, this may be the case for semiconductor LED multilayer stacks mounted onto electrically conductive substrates (e.g., also referred to as mount and/or sub-mounts), such as copper-based or copper-tungsten based substrates. Multiple dies on a wafer may be separated from each other, for example, due to trenches (also referred to as streets) that separate the active layers (e.g., quantum wells) of each die.

On-wafer test system 100 may include a wafer chuck 102 which can support wafer 110. The backside of wafer 110 may be in contact with the surface of the wafer chuck 102. In some embodiments, part or all of wafer chuck 102 may be electrically conductive and can provided for a backside electrical contact with wafer 110. Wafer chuck 102 may also hold wafer 110 in place via vacuum suction and/or mechanical force so as to prevent the wafer from moving during testing.

On-wafer test system 100 may include a probe card 130 comprising one or more probe pins 132. Probe pins 132 may provide for contact with contact bond pads of the light-emitting die of wafer 110. Probe pins 132 may be secured in place using a mechanical securing component 134, such as an insulating ring (e.g., ceramic ring) that surrounds an opening of probe card 130 through which probe pins 132 protrude, as shown in cross-section in FIG. 1.

On-wafer test system 100 may include a power source (e.g., current supply) 140 that may have a terminal connected to probe card 130 (an hence probe pins 132) via an electrical connection (e.g., conductive wire) 142 and an opposite-polarity terminal connected to wafer chuck 102 (an hence the backside of wafer 110, when wafer chuck 102 is electrically conductive) via another electrical connection (e.g., conductive wire) 144. When power (e.g., electrical current) is supplied to the light-emitting die of wafer 110, emitted light 112 can be partially or completely collected through the opening 151 of integrating sphere 150.

In some embodiments, the light-collection component has a cross-sectional dimension (e.g., diameter) of at least about 4 inches (e.g., at least about 6 inches, at least about 8 inches, at least about 12 inches). In some embodiments, the light-collection opening 151 of the integrating sphere may have a diameter of at least about 1 inch (e.g., at least about 2 inches, at least about 4 inches). In some embodiments, the probe card 130 may have a probe pin opening of at least about 1 inch (e.g., at least about 2 inches, at least about 4 inches). In some embodiments, the wafer 110 has a diameter of at least about 2 inches (e.g., at least about 4 inches, at least about 6 inches, at least about 8 inches). In some embodiments, during on-wafer test, the distance between the surface of the light-emitting die of wafer 110 and the light-collection opening 151 of integrating sphere 150 may be less than about 3 cm (e.g., less than about 2 cm, less than about 1 cm).

In some embodiments, during on-wafer test, light emitted within at least about a 30 degree cone from the normal (e.g., at least about a 45 degree cone, at least about a 60 degree cone) is collected (e.g., by the integrating sphere 150). In some embodiments, during on-wafer test, substantially all (e.g., greater than about 70%, greater than about 80%, greater than about 90%, about 100%) of the total emitted light is collected (e.g., by the integrating sphere 150).

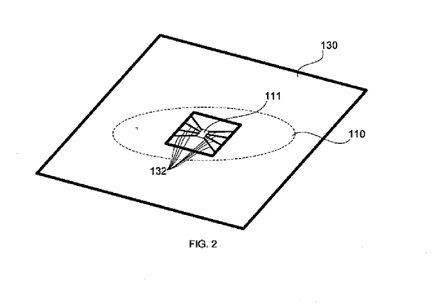

FIG. 2 is a perspective view of a probe card of the on-wafer light-emitting die test system of FIG. 1, in accordance with one embodiment. The components illustrated include the probe card 130 with probe pins 132 and wafer 110 with light-emitting die 111 (e.g., LED die). Probe pins 132 are shown contacting the surface of die 111.

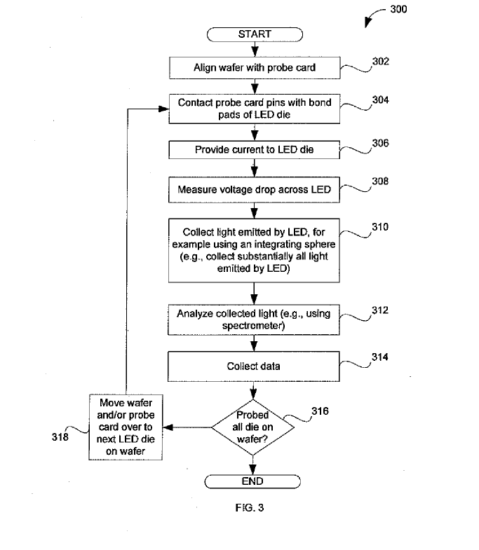

FIG. 3 is a flowchart 300 of a method for performing on-wafer testing of a light-emitting die, in accordance with one embodiment. After a wafer is placed on the wafer chuck 101, the wafer may be aligned with a probe card (act 302). Alignment may be performed with a visual recognition system and may be arranged to place contact bond pads of a light-emitting die on the wafer (e.g., a center die) under the ends of the probe pins 132. Upon alignment, contact of the probe pins 132 with the bond pads of the die may be made (act 304). Probe pin contact may be made be raising the wafer chuck 102 and/or lowering the probe card 130.

After probe pin contact, current may be provided to the light-emitting die (act 306). Electrical current may flow through the die via the wafer chuck and the probe pins (e.g., current can flow from the wafer chuck, through the die, and out the probe pins, or vice versa). The voltage drop through the light-emitting die may be measured during light emission (act 308). In some embodiments, the probe card 130 may include one or more sense pins that allow for the measurement of the voltage drop through the light-emitting die.

At least some, or in some embodiments substantially all, of the light emitted by the light-emitting die may be collected (act 310). A light-collection component may be used to collect light emitted by the light-emitting die. In some embodiments, the light-collection component may include a light integrating sphere, as previously described. The collected light may then be analyzed (act 312). In some embodiments, the total light intensity may be provided based on the electrical output of a broadband photodetector. Alternatively, or additionally, a spectrometer may be used to provide light intensity versus wavelength data.

Light output data may be collected (act 314) and stored for further reference and/or use. Light output data may be used to determine whether a light-emitting die on a wafer meets specification requirement and whether it should be further processed, for example whether the die should be packaged. Alternatively, or additionally, the collected light data may be used to bin the light-emitting die according to binning specifications.

Upon completing probing and light collection of a given die on the wafer, a determination can be made as to whether all the die that were to be tested have been probed (act 316). If it is determined that all the desired light-emitting die have probed, the wafer test may terminate, the wafer may be removed from the wafer chuck, and another wafer can be tested using the same method. If it is determined that further light-emitting dies on the wafer are to be tested, the wafer can be moved relative the probe pins (e.g., by moving the wafer chuck and/or the probe card) such that the probe pins reside over the contact bond pads of the next die to be tested (act 318). The process can then continue with contacting the probe pins to the die, as previously described for act 304, and the method can proceed as described.

The testing apparatus and/or methods described can be used in connection with any type of wafer including light-emitting dies. Such light-emitting die can include large-area dies, as previously described.

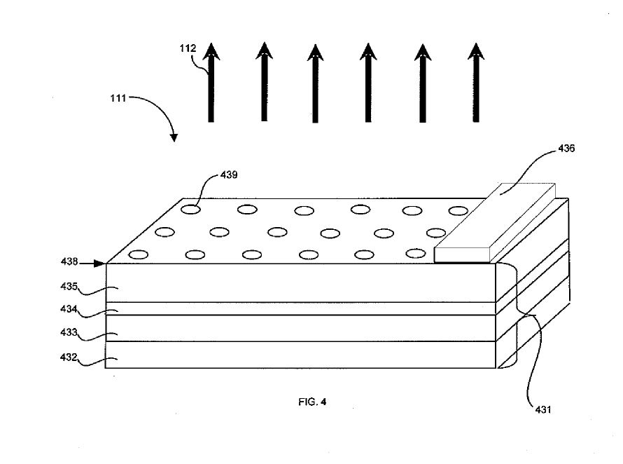

FIG. 4 is a schematic of a light-emitting die, in accordance with one embodiment. It should be understood that various embodiments presented herein can also be applied to other light-emitting dies, such as laser diode dies and LED dies having different structures (such as organic LEDs, also referred to as OLEDs). LED die 111 shown in FIG. 4 comprises a multi-layer stack 431 that may be disposed on a support structure, such as a mount or submount wafer (not shown). The multi-layer stack 431 can include an active region 434 which is formed between n-doped layer(s) 435 and p-doped layer(s) 433. The stack can also include an electrically conductive layer 432 which may serve as a p-side contact, which can also serve as an optically reflective layer. An n-side contact pad 436 may be disposed on layer 435. Electrically conductive fingers (not shown) may extend from the contact pad 436 and along the surface 438, thereby allowing for uniform current injection into the LED structure.

It should be appreciated that the LED is not limited to the configuration shown in FIG. 4, for example, the n-doped and p-doped sides may be interchanged so as to form a LED having a p-doped region in contact with the contact pad 436 and an n-doped region in contact with layer 432. As described further below, electrical potential may be applied to the contact pads which can result in light generation within active region 434 and emission of at least some of the light generated through a light emission surface 438. As described further below, holes 439 may be defined in an emission surface to form a pattern that can influence light emission characteristics, such as light extraction and/or light collimation. It should be understood that other modifications can be made to the representative LED structure presented, and that embodiments are not limited in this respect.

The active region of an LED can include one or more quantum wells surrounded by barrier layers. The quantum well structure may be defined by a semiconductor material layer (e.g., in a single quantum well), or more than one semiconductor material layers (e.g., in multiple quantum wells), with a smaller electronic band gap as compared to the barrier layers. Suitable semiconductor material layers for the quantum well structures can include InGaN, AlGaN, GaN and combinations of these layers (e.g., alternating InGaN/GaN layers, where a GaN layer serves as a barrier layer). In general, LEDs can include an active region comprising one or more semiconductors materials, including III-V semiconductors (e.g., GaAs, AlGaAs, AlGaP, GaP, GaAsP, InGaAs, InAs, InP, GaN, InGaN, InGaAlP, AlGaN, as well as combinations and alloys thereof), II-VI semiconductors (e.g., ZnSe, CdSe, ZnCdSe, ZnTe, ZnTeSe, ZnS, ZnSSe, as well as combinations and alloys thereof), and/or other semiconductors. Other light-emitting materials are possible such as quantum dots or organic light-emission layers.

The n-doped layer(s) 435 can include a silicon-doped GaN layer (e.g., having a thickness of about 4000 nm thick) and/or the p-doped layer(s) 433 include a magnesium-doped GaN layer (e.g., having a thickness of about 40 nm thick). The electrically conductive layer 432 may be a silver layer (e.g., having a thickness of about 100 nm), which may also serve as a reflective layer (e.g., that reflects upwards any downward propagating light generated by the active region 134). Furthermore, although not shown, other layers may also be included in the LED; for example, an AlGaN layer may be disposed between the active region 434 and the p-doped layer(s) 433. It should be understood that compositions other than those described herein may also be suitable for the layers of the LED.

As a result of holes 439, the LED can have a dielectric function that varies spatially according to a pattern. Typical hole sizes can be less than about one micron (e.g., less than about 750 nm, less than about 500 nm, less than about 250 nm) and typical nearest neighbor distances between holes can be less than about one micron (e.g., less than about 750 nm, less than about 500 nm, less than about 250 nm). Furthermore, as illustrated in the figure, the holes 439 can be non-concentric.

The dielectric function that varies spatially according to a pattern can influence the extraction efficiency and/or collimation of light emitted by the LED. In some embodiments, a layer of the LED may have a dielectric function that varies spatially according to a pattern. In the illustrative LED die 111, the pattern is formed of holes, but it should be appreciated that the variation of the dielectric function at an interface need not necessarily result from holes. Any suitable way of producing a variation in dielectric function according to a pattern may be used. The pattern may be periodic (e.g., having a simple repeat cell, or having a complex repeat super-cell), or non-periodic. As referred to herein, a complex periodic pattern is a pattern that has more than one feature in each unit cell that repeats in a periodic fashion. Examples of complex periodic patterns include honeycomb patterns, honeycomb base patterns, (2×2) base patterns, ring patterns, and Archimedean patterns. In some embodiments, a complex periodic pattern can have certain holes with one diameter and other holes with a smaller diameter. As referred to herein, a non-periodic pattern is a pattern that has no translational symmetry over a unit cell that has a length that is at least 50 times the peak wavelength of light generated by one or more light-generating portions. As used herein, peak wavelength refers to the wavelength having a maximum light intensity, for example, as measured using a spectroradiometer. Examples of non-periodic patterns include aperiodic patterns, quasi-crystalline patterns (e.g., quasi-crystal patterns having 8-fold symmetry), Robinson patterns, and Amman patterns. A non-periodic pattern can also include a detuned pattern (as described in U.S. Pat. No. 6,831,302 by Erchak, et al., which is incorporated herein by reference). In some embodiments, a light-emitting die may include a roughened surface. The surface roughness may have, for example, a root-mean-square (rms) roughness about equal to an average feature size which may be related to the wavelength of the emitted light.

In certain embodiments, an interface of a light-emitting device is patterned with holes which can form a photonic lattice. Suitable LEDs having a dielectric function that varies spatially (e.g., a photonic lattice) have been described in, for example, U.S. Pat. No. 6,831,302 B2, entitled “Light emitting devices with improved extraction efficiency,” filed on Nov. 26, 2003, which is herein incorporated by reference in its entirety. A high extraction efficiency for an LED implies a high power of the emitted light and hence high brightness which may be desirable in various optical systems.

It should also be understood that other patterns are also possible, including a pattern that conforms to a transformation of a precursor pattern according to a mathematical function, including, but not limited to an angular displacement transformation. The pattern may also include a portion of a transformed pattern, including, but not limited to, a pattern that conforms to an angular displacement transformation. The pattern can also include regions having patterns that are related to each other by a rotation. A variety of such patterns are described in U.S. Patent Publication No. 20070085098, entitled “Patterned devices and related methods,” filed on Mar. 7, 2006, which is herein incorporated by reference in its entirety.

Light may be generated by the LED as follows. The p-side contact layer can be held at a positive potential relative to the n-side contact pad, which causes electrical current to be injected into the LED. As the electrical current passes through the active region, electrons from n-doped layer(s) can combine in the active region with holes from p-doped layer(s), which can cause the active region to generate light. The active region can contain a multitude of point dipole radiation sources that generate light with a spectrum of wavelengths characteristic of the material from which the active region is formed. For InGaN/GaN quantum wells, the spectrum of wavelengths of light generated by the light-generating region can have a peak wavelength of about 445 nanometers (nm) and a full width at half maximum (FWHM) of about 30 nm, which is perceived by human eyes as blue light. The light emitted by the LED may be influenced by any patterned surface through which light passes, whereby the pattern can be arranged so as to influence light extraction and/or collimation.

In other embodiments, the active region can generate light having a peak wavelength corresponding to ultraviolet light (e.g., having a peak wavelength of about 370-390 nm), violet light (e.g., having a peak wavelength of about 390-430 nm), blue light (e.g., having a peak wavelength of about 430-480 nm), cyan light (e.g., having a peak wavelength of about 480-500 nm), green light (e.g., having a peak wavelength of about 500 to 550 nm), yellow-green (e.g., having a peak wavelength of about 550-575 nm), yellow light (e.g., having a peak wavelength of about 575-595 nm), amber light (e.g., having a peak wavelength of about 595-605 nm), orange light (e.g., having a peak wavelength of about 605-620 nm), red light (e.g., having a peak wavelength of about 620-700 nm), and/or infrared light (e.g., having a peak wavelength of about 700-1200 nm).

In certain embodiments, the LED may emit light having a high light output power. As previously described, the high power of emitted light may be a result of a pattern that influences the light extraction efficiency of the LED. For example, the light emitted by the LED may have a total power greater than 0.5 Watts (e.g., greater than 1 Watt, greater than 5 Watts, or greater than 10 Watts). In some embodiments, the light generated has a total power of less than 100 Watts, though this should not be construed as a limitation of all embodiments. The total power of the light emitted from an LED can be measured by using an integrating sphere equipped with spectrometer, for example a SLM12 from Sphere Optics Lab Systems.

In some embodiments, the LED die may include large-area dies having a light emission area greater than about 1 mm² (e.g., greater than about 3 mm², greater than about 5 mm², greater than about 8 mm², greater than about 10 mm²). In some embodiments, the LED die can include light extraction features (e.g., patterning and/or surface roughness).

The light generated by the LED may also have a high total power flux. As used herein, the term “total power flux” refers to the total optical power divided by the emission area. In some embodiments, the total power flux is greater than 0.03 Watts/mm², greater than 0.05 Watts/mm², greater than 0.1 Watts/mm², or greater than 0.2 Watts/mm². However, it should be understood that the LEDs used in systems and methods presented herein are not limited to the above-described power and power flux values.

In some embodiments, the LED may be associated with one or more wavelength converting regions. The wavelength converting region(s) may include one or more phosphors and/or quantum dots. The wavelength converting region(s) can absorb light emitted by the light-generating region of the LED and emit light having a different wavelength than that absorbed. In this manner, LEDs can emit light of wavelength(s) (and, thus, color) that may not be readily obtainable from LEDs that do not include wavelength converting regions. In some embodiments, one or more wavelength converting regions may be disposed over (e.g., directly on) the emission surface (e.g., surface 438) of the light-emitting device.

As used herein, when a structure (e.g., layer, region) is referred to as being “on”, “over” “overlying” or “supported by” another structure, it can be directly on the structure, or an intervening structure (e.g., layer, region) also may be present. A structure that is “directly on” or “in contact with” another structure means that no intervening structure is present.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. An on-wafer LED test system comprising:
a wafer including an LED die designed to emit light;
a light-collection component configured to collect substantially all of the emitted light and to scatter the emitted light to produce a distribution of scattered light; and
a detector associated with the light-collection component and designed to detect a portion of the scattered light.

2. The system of claim 1, wherein the light-collection component is an integrating sphere.

3. The system of claim 1, wherein the LED die has an area greater than about 1 mm².

4. The system of claim 1, wherein the LED die has an area greater than about 5 mm².

5. The system of claim 1, wherein an interior surface of the light-collection component is coated.

6. The system of claim 1, wherein the distribution of scattered light is uniform across an interior surface of the light-collection component.

7. The system of claim 1, wherein the detector is positioned within the light-collection component.

8. A method of performing an on-wafer LED test, the method comprising:
collecting within a light-collection component substantially all light emitted by a LED die of a wafer; and
scattering the emitted light within the light-collection component to produce a distribution of scattered light; and
detecting a portion of the scattered light.

9. The method of claim 8, wherein collecting substantially all of the light emitted by the LED die of the wafer comprises collecting substantially all of the light emitted by the LED die of the wafer with an integrating sphere.

10. The method of claim 8, wherein the LED die has an area greater than about 1 mm².

11. The method of claim 8, wherein the LED die has an area greater than about 5 mm².

12. The method of claim 8, wherein the distribution of scattered light is uniform across an interior surface of the light-collection component.
